(19) United States
(12) Patent Application Publication
(10) Pub. No.: US 2020/0354831 A1
(43) Pub. Date: Nov. 12, 2020

(54) METHODS AND SYSTEMS FOR CLEANING DEPOSITION SYSTEMS

(71) Applicant: ALTA DEVICES, INC., Sunnyvale, CA (US)

(72) Inventors: Roger HAMAMJY, San Jose, CA (US); Henry LEE, San Jose, CA (US)

(21) Appl. No.: 16/405,347

(22) Filed: May 7, 2019

(51) Int. Cl. C23C 16/44; B08B 3/08; B08B 3/12

(52) U.S. Cl. CPC C23C 16/4407; B08B 3/12; B08B 3/08

(57) ABSTRACT

Aspects of the present disclosure include methods, apparatuses, and computer readable media for transporting, via an automated crane, a component toward a first station within a cleaning system, placing, via the automated crane, the component into a first tank at the first station, wherein the first tank contains a solution that cleans the component by removing at least a portion of residual materials on the component, transporting, via the automated crane, the component toward a second station within a cleaning system, placing, via the automated crane, the component into a second tank at the second station, wherein the second tank contains a fluid that rinses the at least a portion of the residual materials removed by the solution, transporting, via the automated crane, the component toward a third station within a cleaning system, and placing, via the automated crane, the component into a chamber at the third station, wherein the chamber provides a gas or air that dries the fluid on the component.

### BACKGROUND

Depositions systems used in the fabrication of semiconductor devices, such as, for example, a metal-organic chemical vapor deposition (MOCVD) system, a sputter, an evaporator, an atomic layer deposition (ALD) system, a chemical vapor deposition (CVD) system, a plasma enhanced chemical vapor deposition (PECVD) system, a pulsed laser ablation (PLA) system, an atmospheric pressure chemical vapor deposition (APCVD) system, and a sub-atmospheric chemical vapor deposition (SACVD) system, are configured to deposit one or more layers of metal, semiconductor and/or dielectric insulators onto a wafer/substrate. The materials deposited may depend on the source material, which may include solid targets (e.g., sputter), liquid source materials (e.g., H₂O in a bubbler), and/or gas (e.g., Silane gas). While each deposition process may deposit desired materials onto a wafer/substrate as intended, the deposition process may also result in some amounts of the materials (“residual materials”) being deposited onto the walls/shields, the showerheads, the inlets, and other components inside the chamber of the deposition system. The residual materials may include residual liquid or solid chemicals and/or materials.

To minimize contamination, the components of the deposition systems may require physical cleaning (e.g., abrasive) and/or chemical (e.g., solution-based) cleaning after a certain period of time or a certain number of uses. The cleaning may be important to reduce or prevent unintentional deposition of residual materials back onto the wafer/substrate during subsequent deposition processes. However, cleaning may be difficult for components of larger chambers or reactors used in manufacturing due to difficulties in handling and transporting the shields, the showerheads, and other large-sized components. For example, removing such components for cleaning at an external facility may be difficult to handle and may cause costly delays while manufacturing is shut down until clean components are available. Therefore, improvements in the techniques and systems for handling the cleaning of large-sized components may be desirable.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Aspects of the present disclosure include methods for transporting, via an automated crane, a component toward a first station within a cleaning system, placing, via the automated crane, the component into a first tank at the first station, wherein the first tank contains a solution that cleans the component by removing at least a portion of residual materials on the component, transporting, via the automated crane, the component toward a second station within a cleaning system, placing, via the automated crane, the component into a second tank at the second station, wherein the second tank contains a fluid that rinses the at least a portion of the residual materials removed by the solution, transporting, via the automated crane, the component toward a third station within a cleaning system, and placing, via the automated crane, the component into a chamber at the third station, wherein the chamber provides a gas or air that dries the fluid on the component.

Other aspects of the present disclosure include a first tank configured to contain a solution that removes at least a portion of residual materials on the component, a second tank configured to contain a fluid that rinses the at least a portion of residual materials removed by the solution, a chamber configured to provide a gas or air that dries the component, and a hoist system that transports the component from the first tank to the second tank or from the second tank to the chamber.

An aspect of the present disclosure includes means for transporting, via an automated crane, a component toward a first station within a cleaning system, means for placing, via the automated crane, the component into a first tank at the first station, wherein the first tank contains a solution that cleans the component by removing at least a portion of residual materials on the component, means for transporting, via the automated crane, the component toward a second station within a cleaning system, means for placing, via the automated crane, the component into a second tank at the second station, wherein the second tank contains a fluid that rinses the at least a portion of the residual materials removed by the solution, means for transporting, via the automated crane, the component toward a third station within a cleaning system, and means for placing, via the automated crane, the component into a chamber at the third station, wherein the chamber provides a gas or air that dries the fluid on the component.

Some aspects of the present disclosure include non-transitory computer readable media having instructions stored therein that, when executed by one or more processors of a control system of an automated crane inside a cleaning system, cause the crane to perform the steps of transporting a component toward a first station within a cleaning system, placing the component into a first tank at the first station, wherein the first tank contains a solution that cleans the component by removing at least a portion of residual materials on the component, transporting the component toward a second station within a cleaning system, placing the component into a second tank at the second station, wherein the second tank contains a fluid that rinses the at least a portion of the residual materials removed by the solution via the automated crane, the component toward a third station within a cleaning system, and placing the component into a chamber at the third station, wherein the chamber provides a gas or air that dries the fluid on the component.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is an example of a cleaning system according certain aspects of the present disclosure.

FIGS. 2A-B are examples of a cleaning system according certain aspects of the present disclosure.

FIG. 3 is an example of a removal tank according certain aspects of the present disclosure.

FIG. 4 is an example of a rinsing tank according certain aspects of the present disclosure.

FIG. 5 is an example of a drying chamber according certain aspects of the present disclosure.

FIG. 6 is another example of a cleaning system according certain aspects of the present disclosure.

FIG. 7 is an example computer system according certain aspects of the present disclosure.

FIG. 8 is a process flow diagram of an example of cleaning.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Aspects of the present disclosure includes a cleaning system for various components of a deposition system. The cleaning system may include one or more stations. Stations may be separate areas, regions, or modules within the cleaning system intended to carry out a separate and/or different processes. In some examples, a first station of the one or more stations may include one or more cleaning tanks having cleaning chemicals for removing residual materials deposited onto the components of the deposition system. A second station of the one or more stations may include one or more rinsing tanks for removing the cleaning chemicals and remaining residual materials from the components via deionized (DI) water. A third station of the one or more stations may include a drying chamber for removing any remaining deionized water on the components. The components may be automatically moved from one station to another via a hoist.

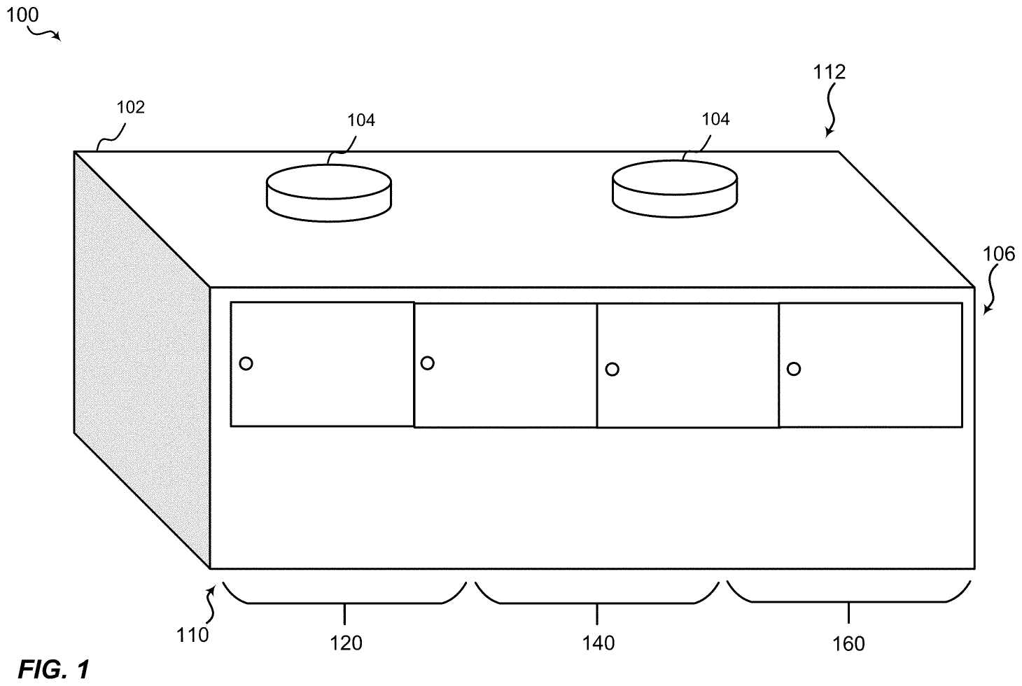

Referring to FIG. 1, in certain aspects, a cleaning system 100 may include an enclosure 102, one or more exhausts 104, one or more sliding panels 106, a first station 120, a second station 140, and a third station 160. The enclosure 102 may be sealed to prevent vapor from escaping other than through the one or more exhausts.

In some aspects, the one or more exhausts 104 may be connected to a negative pressure ventilation system (not shown) configured to vent fumes in the enclosure 102 of the cleaning system 100. The fumes generated during the cleaning process may be harmful if inhaled by operators. The one or more exhausts 104 and the negative pressure ventilation system may vent the fumes out of the enclosure 102 to maintain safety of the operators.

The sliding panels 106 may be glass, polyethylene, or materials. The sliding panels 106 may be transparent or opaque. The sliding panels 106 may slide along rails (not shown) to allow operators (not shown) access to the first station 120, the second station 140, and/or the third station 160.

In some implementations, the cleaning system 100 may include the first station 120 configured for removing residual chemicals and/or materials (e.g., solid materials) from components of the deposition system (not shown). The removal process may include a chemical cleaning and/or a physical cleaning. The chemical cleaning process may include spraying the components with chemical solutions and/or immersing and/or submerging the components in the chemical solutions. The chemical cleaning process may cause the residual chemicals and/or materials (e.g., solid materials) to peel off the components or to react with the chemical solutions. The product of the reaction between the residual chemicals and/or materials (e.g., solid materials) and the chemical solutions may become soluble in a rinsing solution (e.g., DI water), and be rinsed off at a later time. The physical cleaning process may include abrasively “buff” the surfaces of the components to remove the residual chemicals and/or materials (e.g., solid materials). In some implementations, the physical cleaning process may be performed before or after the cleaning process. In certain examples, the physical cleaning process may be performed outside of the enclosure 102. In other examples, the physical cleaning process may be performed in the enclosure 102 (e.g., in the first station 120). The first station 120 may be optionally equipped with a sandblaster for abrasively clean the components.

In certain implementations, the second station 140 may be configured to rinse the components after the cleaning process. The rinsing process may include spraying the components with DI water and/or immersing the components in the DI water. The spraying process may rinse the residual chemicals, materials (e.g., solid materials), and/or the products of the reaction (e.g., products of reaction in the first station that did not get removed), and/or delaminate the residual chemicals and/or materials (e.g., solid materials) from surfaces of the components (e.g., deposited chemicals or materials that did not react with the chemical solutions and are still adhering to the surfaces of the components).

In some examples, the third station 160 may be configured to dry the components after the rinsing process. The drying process may include blowing compressed dry air (CDA) or nitrogen gas (N₂) toward the components. In some examples, the CDA or the N₂ gas may be room temperature. In other implementations, the CDA or N₂ may be heated to, for example, accelerate the drying process.

In some aspects of the present disclosure, the residual materials and/or materials (e.g., solid materials) may include gallium arsenide, gallium arsenide phosphide, gallium phosphide, aluminum gallium arsenide, aluminum gallium nitride, aluminum gallium indium phosphide, aluminum gallium indium nitride, aluminum gallium, aluminum phosphide, aluminum nitride, zinc selenide, indium gallium nitride, indium gallium arsenide, silicon carbide, or other elemental, molecular (e.g., group II-VI and/or III-V compounds), or organic semiconductors.

The components may include walls/shields, showerheads, inlets, gauges, observation windows, carriers, stages, valves, and other components of the deposition system.

During normal operations, in certain aspects of the present disclosure, the components may be loaded into the enclosure 102 from a front side 110 of the cleaning system 100. The operator may load the components by opening one or more of the sliding panels 106 and placing the components into the enclosure 102 for the cleaning process. In some implementations, the operator may start the cleaning process by loading the components into the first station 120 for the removal process. The cleaning process may be automated or manually controlled.

In some examples, a rear side 112 of the cleaning system 100 may include one or more access panels for allowing operators to clean, repair, maintain, upgrade, install, and/or replace equipment in the cleaning system 100. The rear side 112 may include pipes, electrical wiring, gas tank storage, DI water generator, or other equipment for the cleaning system 100.

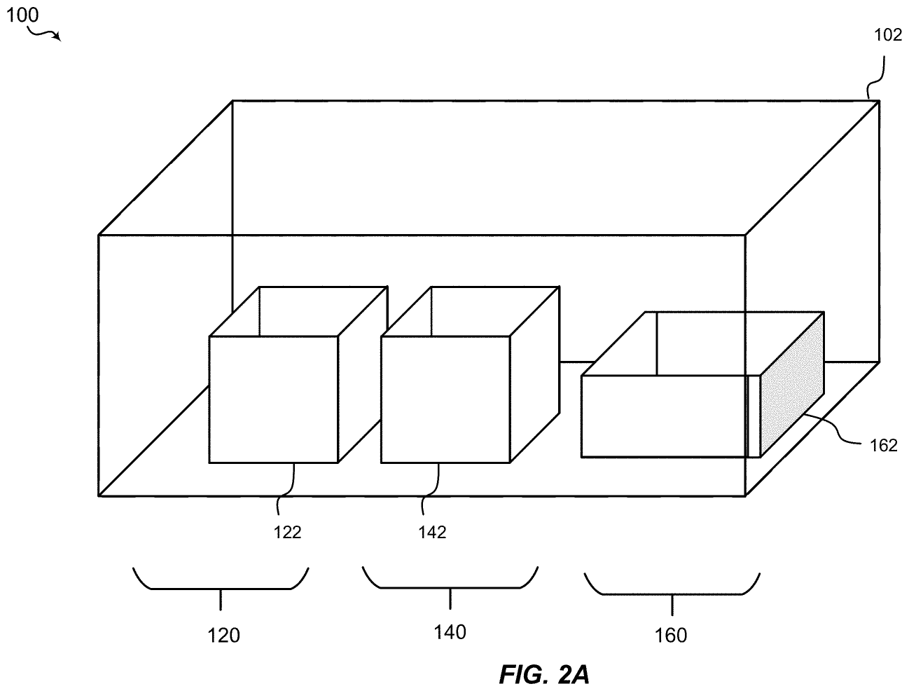

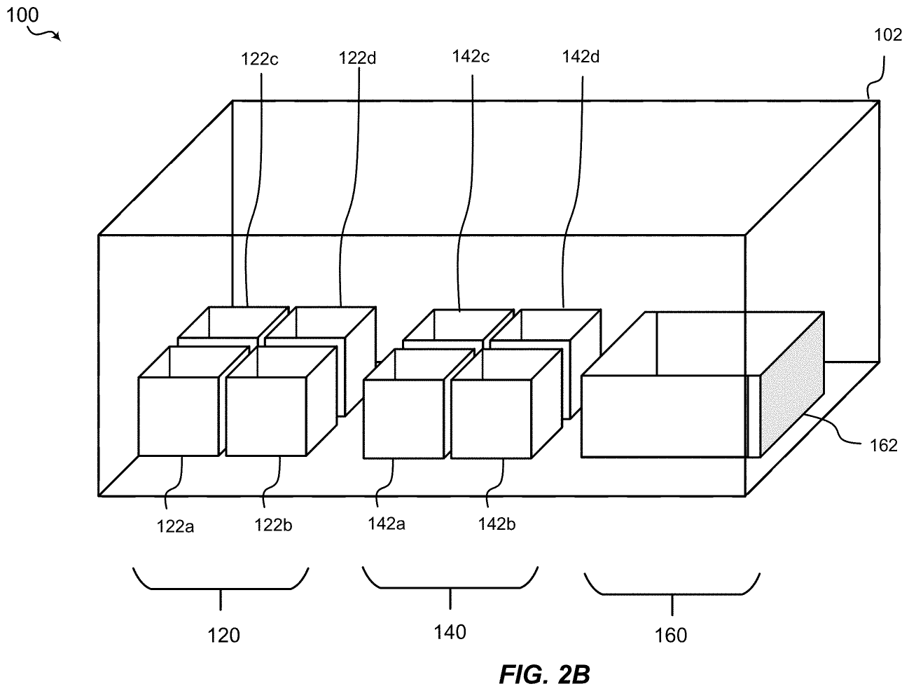

Turning now to FIG. 2A, according to an aspect of the present disclosure, the first station 120 may include a cleaning tank 122. The cleaning tank 122 may contain a chemical solution. The chemical solution may include one or more of the following: ammonium hydroxide (NH₄OH), hydrogen peroxide (H₂O₂), sulfuric acid (H₂SO₄), hydrochloric acid (HCl), hydrofluoric acid (HF), methanol, acetone, and iso-propyl alcohol (IPA). In one non-limiting example, the cleaning tank 122 may include a mixture of NH₄OH and H₂O₂ (e.g., 1:1 ratio), a mixture of H₂SO₄ and H₂O₂ (e.g., 1:1 ratio), acetone, IPA, or HCl and H₂O₂ (e.g., 1:1 ratio). Other combinations of chemical solutions and ratios may be used. In some circumstances, the solutions used may depend on the residual materials and/or materials (e.g., solid materials) on the components. In some examples, the first station 120 may include a single cleaning tank to accommodate large components.

In another aspect, the second station 140 may include a rinsing tank 142. The rinsing tank 142 may include DI water. In other aspects, the second station 140 may include a single rinsing tank to accommodate large components. The rinsing tank 142 may include one or more multi-meters to measure the resistivity of the DI water in the rinsing tank 142 to determine the cleanliness of the DI water.

In some examples, the third station 160 may include a drying chamber 162. The drying chamber 162 may be configured to provide CDA or N₂ to dry the components after the cleaning process.

During normal operations, the operator (not shown) may load the components into the enclosure 102 for cleaning. The components may be immersed into the chemical solutions in the cleaning tank 122 for removing the residual materials and/or materials (e.g., solid materials). Next, the components may be immersed into the DI water in the rinsing tank 142 to remove the chemical solutions and/or remaining residual materials and/or materials (e.g., solid materials). Next, the components may be placed in the drying chamber 162 to remove the DI water.

Turning now to FIG. 2B, according to an aspect of the present disclosure, the first station 120 may include a number of cleaning tanks 122a, 122b, 122c, 122d. The cleaning tanks 122a, 122b, 122c, 122d may contain the same or different chemical solutions. The chemical solutions may include one or more of the following: NH₄OH, H₂O₂, H₂SO₄, HCl, HF, methanol, acetone, and IPA. In one non-limiting example, the cleaning tank 122a may include a mixture of NH₄OH and H₂O₂ (e.g., 1:1 ratio), the cleaning tank 122b may include H₂SO₄ and H₂O₂ (e.g., 1:1 ratio), the cleaning tank 122c may include acetone, and the cleaning tank 122d may include IPA. In another example, the cleaning tank 122a may include a mixture of NH₄OH and H₂O₂ (e.g., 1:1 ratio), the cleaning tank 122b may include HCl and H₂O₂ (e.g., 1:1 ratio), the cleaning tank 122c may include acetone, and the cleaning tank 122d may include IPA. Other combinations of chemical solutions and ratios may be used. In some circumstances, the solutions used may depend on the residual materials and/or materials (e.g., solid materials) on the components. In some examples, the first station 120 may include a single cleaning tank to accommodate large components.

In another aspect, the second station 140 may include a number of rinsing tanks 142a, 142b, 142c, 142d. The cleaning tanks 142a, 142b, 142c, 142d may include DI water. In other aspects, the second station 140 may include a single rinsing tank to accommodate large components.

In some examples, the third station 160 may include a drying chamber 162. The drying chamber 162 may be configured to provide CDA or N₂ to dry the components after the cleaning process.

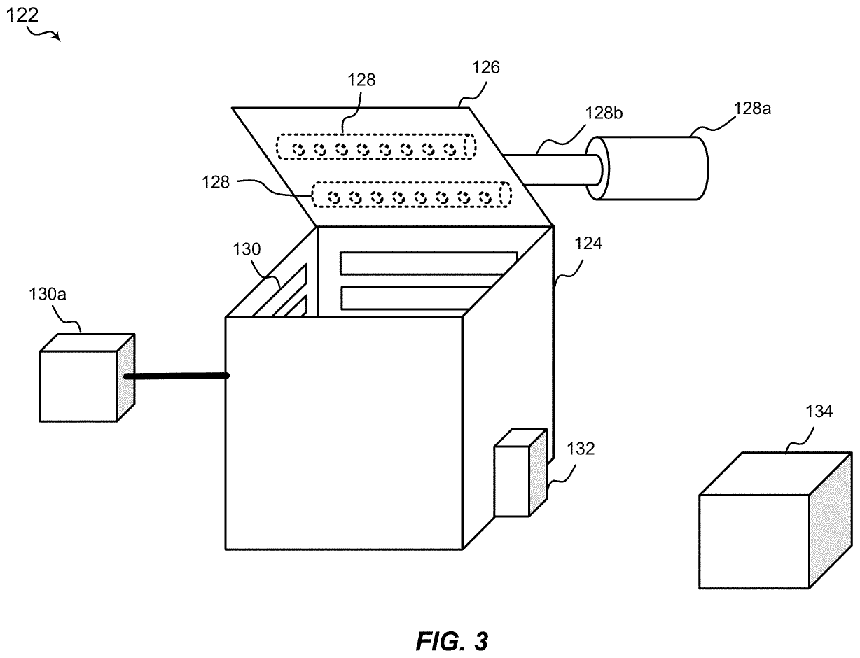

Referring now to FIG. 3, in some implementations, an example of the cleaning tank 122 may include a reservoir 124, a lid 126, one or more optional spray manifolds 128, one or more heating elements 130, an ultrasonic transducer 132, and a controller 134.

In some implementations, the reservoir 124 may be stainless steel. The reservoir 124 may include fill inlets and/or drain outlets. The lid 126 may be pneumatically actuated by an actuator (not shown). The lid 126 may include a single lid or a double lid. The controller 134 may control the opening and closing of the lid 126.

In certain aspects, the one or more optional spray manifolds 128 may be configured for tank wash down or dilution of the chemical solutions. The one or more optional spray manifolds 128 may spray DI water and/or other solutions. A pump 128a may supply DI water to the one or more optional spray manifolds 128 via a tube 128b.

In some implementations, the one or more heating elements 130 may heat the chemical solutions. The one or more heating elements 130 may be heated by a heater 130a that provides electrical energy to the one or more heating elements. The heater 130a may include an integrated thermocouple (not shown) for measuring the temperature of the solutions in the reservoir 124. The heater 130a may control the temperature of the solutions by controlling the power delivered to the one or more heating elements 130 so0 the temperature of the solutions in the reservoir 124 may maintain at a substantially constant temperature. The temperature may be predetermined based on the solutions and the residual chemicals and/or materials (e.g., solid materials).

In some examples, the ultrasonic transducer 132 may provide agitation via sonic waves. The ultrasonic transducer 132 may include an immersion style ultra-sonic array. The ultrasonic transducer 132 may be controlled may a sweep frequency controller.

In non-limiting examples, the controller 134 may control the filling and draining of the solutions in the reservoir 124, the opening and closing of the pneumatically actuated lid 126, the amount and pressure of spraying of the one or more optional spray manifolds 128 via the pump 128a, the heating of the one or more heating elements 130 via the heater 130a, and/or the activation and power of the ultrasonic transducer 132. The controller 134 may include wired or wireless connections.

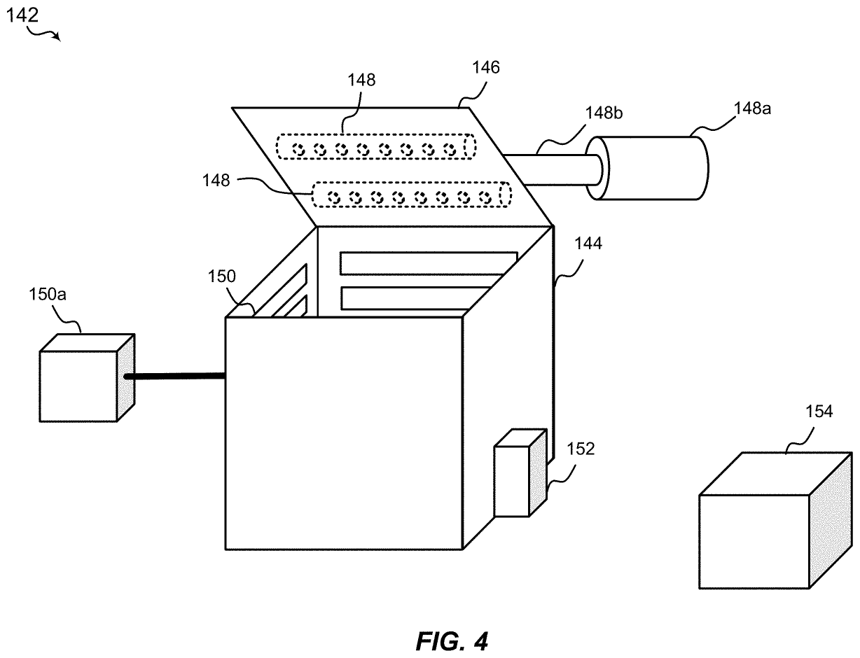

Referring now to FIG. 4, in some implementations, an example of the rinsing tank 142 may include a reservoir 144, a lid 146, one or more optional spray manifolds 148, one or more heating elements 150, an ultrasonic transducer 152, and a controller 154.

In some implementations, the reservoir 144 may be stainless steel. The reservoir 144 may include fill inlets and/or drain outlets. The lid 146 may be pneumatically actuated by an actuator (not shown). The lid 146 may include a single lid or a double lid. The controller 154 may control the opening and closing of the lid 146.

In certain aspects, the one or more optional spray manifolds 148 may be configured for tank wash down or pressurized rinsing. The one or more optional spray manifolds 148 may spray DI water to wash the rinsing tank 142, pressure washing the components. A pump 148a may supply DI water (pressurized) to the one or more optional spray manifolds 148 via a tube 148b.

The drain outlets for the cleaning tank(s) 122 and the rinsing tank(s) 142 may be combined or separate. For example, the drain outlets for the cleaning tank(s) 122 may drain into one or more cleaning reservoirs for handling hazardous chemical solutions. The cleaning reservoirs may allow recovery of materials. The cleaning reservoirs may be diluted with an aspirator and/or water.

In some implementations, the one or more heating elements 150 may heat the DI water in the reservoir 144. The one or more heating elements 150 may be heated by a heater 150a that provides electrical energy to the one or more heating elements. The heater 150a may include an integrated thermocouple (not shown) for measuring the temperature of the DI water in the reservoir 144. The heater 150a may control the temperature of the DI water by controlling the power delivered to the one or more heating elements 150 so the temperature of the DI water in the reservoir 144 may maintain at a substantially constant temperature.

In some examples, the ultrasonic transducer 152 may provide agitation via sonic waves. The ultrasonic transducer 152 may include an immersion style ultra-sonic array. The ultrasonic transducer 152 may be controlled may a sweep frequency controller.

In non-limiting examples, the controller 154 may control the filling and draining of the DI water in the reservoir 144, the opening and closing of the pneumatically actuated lid 146, the amount and pressure of spraying of the one or more spray manifolds 148 via the pump 148a, the heating of the one or more heating elements 150 via the heater 150a, and/or the activation and power of the ultrasonic transducer 152. The controller 154 may include wired or wireless connections.

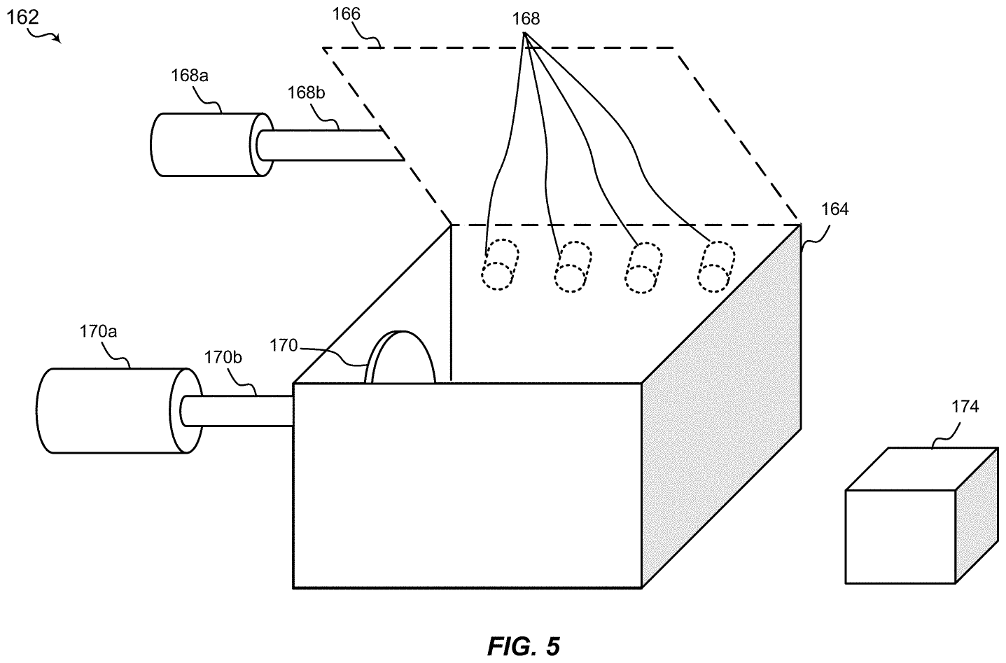

Referring now to FIG. 5, in some implementations, an example of the drying chamber 162 may include a compartment 164, an optional lid 166, one or more optional adjustable nozzles 168, a vent 170, and a controller 174.

In some implementations, the compartment 164 may be stainless steel. The optional lid 166 may be pneumatically actuated by an actuator (not shown). The controller 174 may control the opening and closing of the optional lid 166. The compartment 164 may optionally include heating elements to raise the temperature of the gas inside the compartment 164.

In certain aspects, the one or more optional adjustable nozzles 168 may be configured to inject room temperature or heated CDA or N₂ into the compartment 164. A pump 168a may supply CDA or N₂ to the one or more optional adjustable nozzles 168 via a tube 168b. The optional adjustable nozzles 168 may be adjusted to change the directions of the flow of the CDA or N₂.

In an example, the vent 170 may be connected to a pump 170a via a pipe 170b. The pump 170a may reduce the gas pressure in the compartment 164 via the vent 170 (when the one or more optional nozzles 168 are not introducing CDA or N₂). The decrease in gas pressure inside the compartment 164 may accelerate the drying of the components in the drying chamber 162. The pump 170a may be a mechanical pump.

In non-limiting examples, the controller 174 may control the opening and closing of the pneumatically actuated lid 166, the amount and pressure of the CDA or N₂ from the one or more optional adjustable nozzles 168 via the pump 168a, and/or the air pressure inside the compartment 164 via the pump 170a. The controller 174 may include wired or wireless connections.

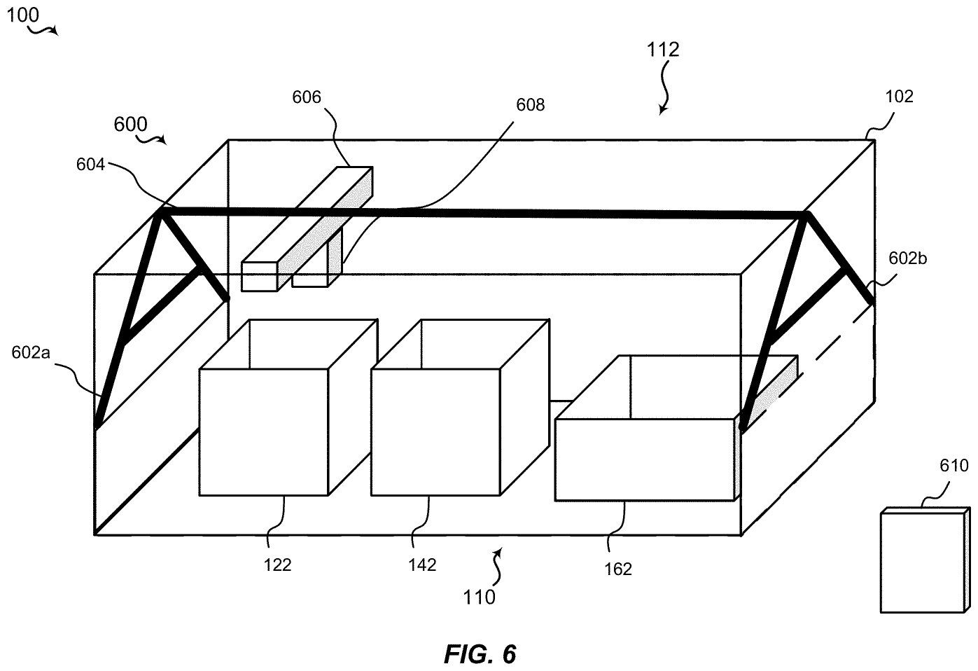

Turning now to FIG. 6, in some implementations, the enclosure 102 may include a crane system 600 for transporting the components from, for example, the first station 120 to the second station 140 (not shown). The crane system 600 may include A-frames 602a, 602b. The A-frames 602a, 602b may be connected to and support a rail 604. The A-frames 602a, 602b and the rail 604 may be configured to support 100 pound (lb), 200 lb, 300 lb, 500 lb, 1000 lb, or more. A horizontal member 606 may be configured to slide along the rail 604 from one of the A-frames 602a, 602b toward another. A attachment member 608 may be configured to slide along the horizontal member 606 (via a track or rail, not shown) between the front side 110 of the enclosure 102 and the back side 112 of the enclosure 102. The attachment member 608 may be configured to couple to a variety of grasping devices (not shown). The grasping devices may be used to stabilize and clench the components as the crane system 600 transports the components from a station to another. In some examples, the grasping devices may include hooks, clamps, claws, frames, baskets, buckets, or other fixtures that may be used to transport the components within the enclosure 102. Other hoist systems may also be used. The crane system 600 may be configured to move, raise, and lower components that weigh 100 lb, 200 lb, 300 lb, 500 lb, 1000 lb, or other weight. The crane system 600 may include pneumatic, hydraulic, electrical, mechanical, or other systems (not shown) to power the movements of the horizontal member 606 along the rail 604 and/or the attachment member 608 along the horizontal member 606. The crane system 600 may also include pneumatic, hydraulic, electrical, mechanical, or other systems (not shown) to power the raising and lowering of the grasping device.

In certain examples, the operation of the crane system 600 may be controlled by a controller 610. The controller 610 may be a hand-held motion controller. In certain instances, one or more of the controllers 134, 154, 174, and 610 may be integrated into a single controller. The removal, rinsing, and drying processes may be programmed into the controllers 134, 154, 174, and 610 to automate the cleaning process. The program may include parameters such as the soaking time of the components in the cleaning tanks 122, the solutions temperature inside the cleaning tanks 122, the activation or deactivation of the ultrasound produced by the ultrasound transducer 132, the rinsing time of the components in the rinsing tanks 142, the DI water temperature in the rinsing tanks 142, the activation or deactivation of the ultrasound produced by the ultrasound transducer 152, the drying time of the components in the drying chamber 162, the temperature of the CDA or N₂ blown by the optional nozzles 168, the pressure inside the compartment 164. One or more of the controllers 134, 154, 174, 610 or the integrated single controller may be implemented by a computer system, such as a computer system 2000.

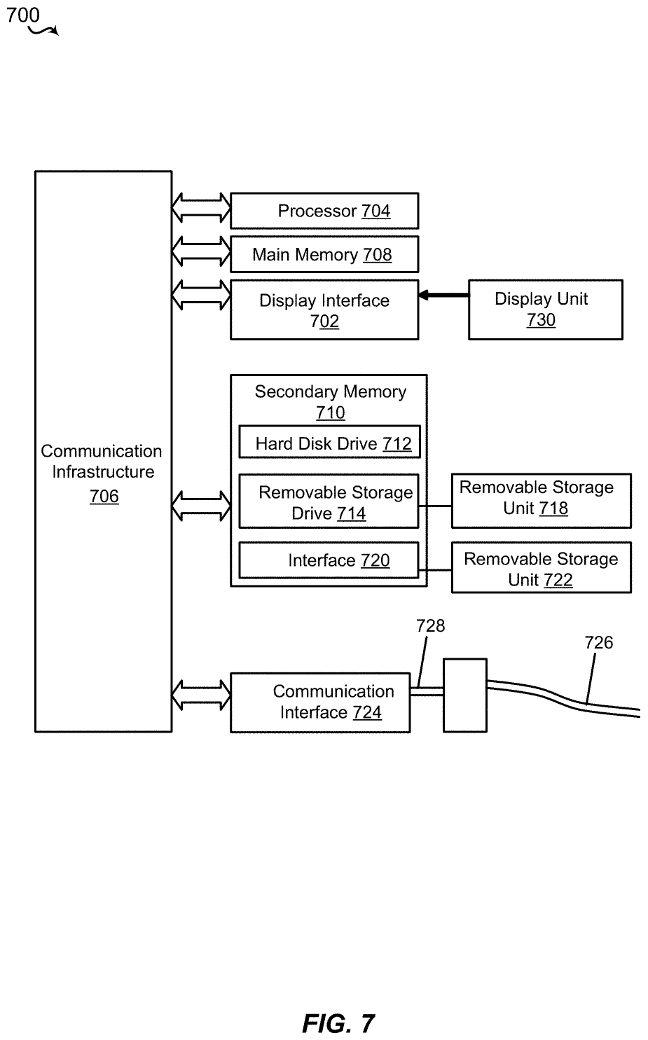

Referring to FIG. 7, the computer system 700 may include a display interface 702 that forwards graphics, text, and other data from the communication infrastructure 706 (or from a frame buffer not shown) for display on a display unit 730. Computer system 700 also includes a main memory 708, preferably random access memory (RAM), and may also include a secondary memory 710. The secondary memory 710 may include, for example, a hard disk drive 712, and/or a removable storage drive 714, representing a floppy disk drive, magnetic tape drive, optical disk drive, universal serial bus (USB) flash drive, etc. The removable storage drive 714 reads from and/or writes to a first removable storage unit 718 in a well-known manner. The first removable storage unit 718 represents a floppy disk, magnetic tape, optical disk, USB flash drive etc., which is read by and written to removable storage drive 714. As will be appreciated, the first removable storage unit 718 includes a computer usable storage medium having stored therein computer software and/or data.

Alternative aspects of the present disclosure may include secondary memory 710 and may include other similar devices for allowing computer programs or other instructions to be loaded into computer system 700. Such devices may include, for example, a second removable storage unit 722 and an interface 720. Examples of such may include a program cartridge and cartridge interface (such as that found in video game devices), a removable memory chip (such as an erasable programmable read only memory (EPROM), or programmable read only memory (PROM)) and associated socket, and other removable storage units (not shown) and interfaces 720, which allow software and data to be transferred from the second removable storage unit 722 to computer system 700.

Computer system 700 may also include a communications interface 724. Communications interface 724 allows software and data to be transferred between computer system 700 and external devices. Examples of communications interface 724 may include a modem, a network interface (such as an Ethernet card), a communications port, a Personal Computer Memory Card International Association (PCMCIA) slot and card, etc. Software and data transferred via communications interface 724 are in the form of signals 728, which may be electronic, electromagnetic, optical or other signals capable of being received by communications interface 724. These signals 728 are provided to communications interface 724 via a communications path (e.g., channel) 726. This path 726 carries signals 728 and may be implemented using one or more of a wire or cable, fiber optics, telephone line, cellular link, RF link and/or other communications channels. In this document, the terms “computer program medium” and “computer usable medium” are used to refer generally to media such as the first removable storage drive 718, a hard disk installed in hard disk drive 712, and signals 728. These computer program products provide software to the computer system 700. Aspects of the present disclosure are directed to such computer program products.

Computer programs (also referred to as computer control logic) are stored in main memory 708 and/or secondary memory 710. Computer programs may also be received via communications interface 724. Such computer programs, when executed, enable the computer system 700 to perform the features in accordance with aspects of the present disclosure, as discussed herein. In particular, the computer programs, when executed, enable the processor 704 to perform the features in accordance with aspects of the present disclosure. Accordingly, such computer programs represent controllers of the computer system 700.

In an aspect of the present disclosure where the method is implemented using software, the software may be stored in a computer program product and loaded into computer system 700 using removable storage drive 714, hard drive 712, or communications interface 720. The control logic (software), when executed by the processor 704, causes the processor 704 to perform the functions described herein. In another aspect of the present disclosure, the system is implemented primarily in hardware using, for example, hardware components, such as application specific integrated circuits (ASICs). Implementation of the hardware state machine so as to perform the functions described herein will be apparent to persons skilled in the relevant art(s).

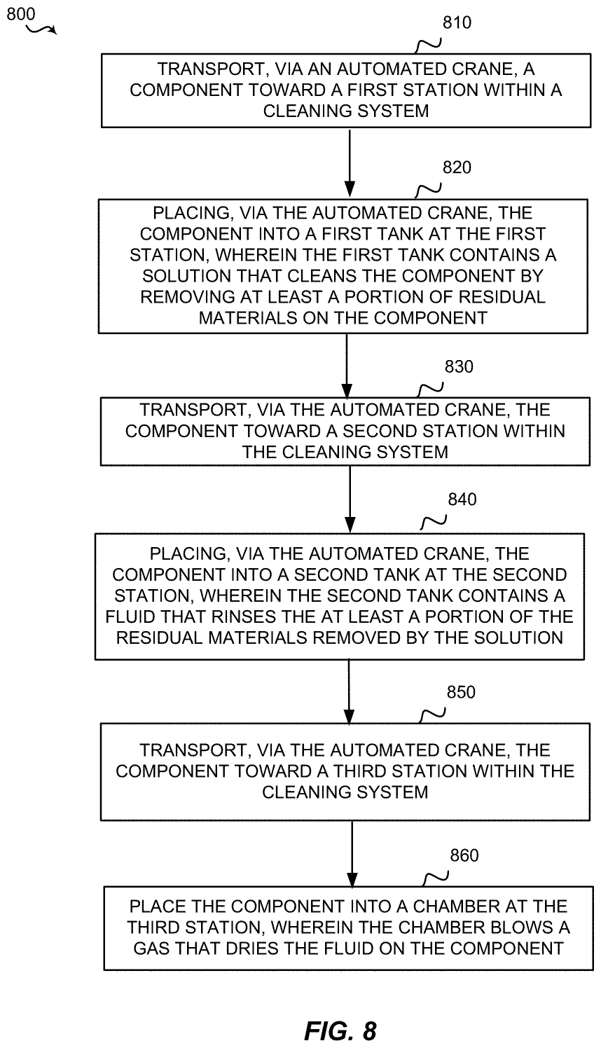

Referring to FIG. 8, an example of a method 800 for automatically cleaning a component of a deposition system.

At block 810, the method 800 may transport, via an automated crane, a component toward a first station within a cleaning system.

At block 820, the method 800 may place, via the automated crane, the component into a first tank at the first station, wherein the first tank contains a solution that cleans the component by removing at least a portion of residual materials on the component.

At block 830, the method 800 may transport, via the automated crane, the component toward a second station within the cleaning system.

At block 840, the method 800 may place the component into a second tank at the second station, wherein the second tank contains a fluid that rinses the at least a portion of the residual materials removed by the solution.

At block 850, the method 800 may transport, via the automated crane, the component toward a third station within the cleaning system.

At block 860, the method 800 may place the component into a chamber at the third station, wherein the chamber blows a gas or air that dries the fluid on the component.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

The various illustrative blocks and components described in connection with the disclosure herein may be implemented or performed with a specially-programmed device, such as but not limited to a processor, a digital signal processor (DSP), an ASIC, a FPGA or other programmable logic device, a discrete gate or transistor logic, a discrete hardware component, or any combination thereof designed to perform the functions described herein. A specially-programmed processor may be a microprocessor, but in the alternative, the processor may be any conventional processor, controller, microcontroller, or state machine. A specially-programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above may be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that may be accessed by a general purpose or special purpose computer. By way of example, and not limitation, computer-readable media may comprise RAM, ROM, EEPROM, CD-ROM or other optical disk storage, magnetic disk storage or other magnetic storage devices, or any other medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method of cleaning one or more components from a reactor chamber used to manufacture semiconductor devices, comprising:
transporting, via an automated crane, a component toward a first station within a cleaning system;
placing, via the automated crane, the component into a first tank at the first station, wherein the first tank contains a solution that cleans the component by removing at least a portion of residual materials on the component;
transporting, via the automated crane, the component toward a second station within the cleaning system;
placing, via the automated crane, the component into a second tank at the second station, wherein the second tank contains a fluid that rinses the at least a portion of the residual materials removed by the solution;
transporting, via the automated crane, the component toward a third station within the cleaning system; and
placing, via the automated crane, the component into a chamber at the third station, wherein the chamber blows a gas or air that dries the fluid on the component.

2. The method of claim 1, further comprises, prior to transporting the component toward the first station, receiving, via the automated crane, the component from a joist system.

3. The method of claim 1, further comprises heating at least one of the first tank or the second tank.

4. The method of claim 1, further comprises applying ultrasonic energy to at least one of the first tank or the second tank while the component is at least partially submerged in the solution or the fluid.

5. The method of claim 1, further comprises spraying the component with the solution in the first tank or with the fluid in the second tank.

6. The method of claim 1, wherein the solution in the first tank includes at least one of ammonium hydroxide (NH₄OH), hydrogen peroxide (H₂O₂), sulfuric acid (H₂SO₄), hydrochloric acid (HCl), hydrofluoric acid (HF), methanol, acetone, and iso-propyl alcohol (IPA).

7. The method of claim 1, wherein the fluid in the second tank includes de-ionized water.

8. The method of claim 7, further comprising measuring the resistivity of the de-ionized water to determine the cleanliness of the de-ionized water.

9. The method of claim 1, wherein the chamber blows compressed dry air or nitrogen gas.

10. The method of claim 1, wherein the automated crane includes a hook, a clamp, a claw, a frame, a basket, or a bucket for attaching or placing the component.

11. The method of claim 1, further comprising draining at least one of the solution in the first tank or the fluid in the second tank.

12. The method of claim 1, further comprising covering the first tank after placing the component into the first tank or covering the second tank after placing the component into the second tank.

13. A cleaning system for cleaning one or more components from a reactor chamber used to manufacture semiconductor devices, comprising:
a first tank configured to contain a solution that removes at least a portion of residual materials on the component;
a second tank configured to contain a fluid that rinses the at least a portion of residual materials removed by the solution;
a chamber configured to blow a gas or air that dries the component; and
a hoist system that transports the component from the first tank to the second tank or from the second tank to the chamber.

14. The cleaning system of claim 13, wherein the first tank further comprises at least one of a heater, a spray manifold, an ultrasonic transducer, and an automated lid.

15. The cleaning system of claim 13, wherein the second tank further comprises at least one of a heater, a spray manifold, an ultrasonic transducer, and an automated lid.

16. The cleaning system of claim 13, wherein the hoist system further comprises:
two or more frames supporting a rail,
an attachment member configured to slide along the rail, and
an interchangeable fixture coupled to the attachment member, wherein the interchangeable fixture is configured to hold the component.

17. The cleaning system of claim 13, further comprising:
an enclosure having one or more access points and one or more exit points, wherein the first tank, the second tank, the chamber, and the hoist system are placed inside the enclosure.

18. The cleaning system of claim 17, wherein the one or more access points or the one or more exit points include transparent sliding panels.

19. The cleaning system of claim 13, wherein the first tank includes a drain outlet and the second tank includes a separate drain outlet.

20. The cleaning system of claim 13, wherein the chamber includes adjustable nozzles.
